(19) United States
(12) Patent Application Publication
(10) Pub. No.: US 2025/0226031 A1
(43) Pub. Date: Jul. 10, 2025

(54) SEMICONDUCTOR MEMORY DEVICE

(71) Applicant: Kioxia Corporation, Tokyo (JP)

(72) Inventors: Yosuke MURAKAMI, Mie Mie (JP); Keisuke NAKATSUKA, Kuwana Mie (JP); Yasuhiro UCHIYAMA, Yokkaichi Mie (JP)

(73) Assignee: Kioxia Corporation, Tokyo (JP)

(21) Appl. No.: 18/829,771

(22) Filed: Sep. 10, 2024

(30) Foreign Application Priority Data
Jan. 4, 2024 (JP) 2024-000280

(51) Int. Cl. G11C 16/04; G11C 16/08; G11C 16/10; G11C 16/24; G11C 16/34; H10B 43/35

(52) U.S. Cl. CPC G11C 16/0483; G11C 16/10; G11C 16/3459; G11C 16/08; G11C 16/24; H10B 43/35

(57) ABSTRACT

According to an embodiment, a semiconductor memory devices includes a first memory string, a bit line, a source line, first and select gate lines, first to third word lines, and a control circuit. The first memory string includes a first selection transistor, first to third memory cells, and a second selection transistor. In a case where data is written to the first memory cell, the control circuit is configured to apply a first voltage to the bit line BL, apply a second voltage to the source line, apply a third voltage to the first select gate line, apply a fourth voltage to the second select gate line, apply a program voltage to the first word line, apply a fifth voltage to the second word line, and apply a sixth voltage to the third word line.

### CROSS-REFERENCE TO RELATED APPLICATION

This application is based upon and claims the benefit of priority from Japanese Patent Application No. 2024-000280, filed Jan. 4, 2024, the entire contents of which are incorporated herein by reference.

### FIELD

Embodiments described herein relate generally to a semiconductor memory device.

### BACKGROUND

A NAND-type flash memory is known as a semiconductor memory device.

### BRIEF DESCRIPTION OF DRAWINGS

FIG. 1 is a block diagram illustrating an overall configuration of a semiconductor memory device according to a first embodiment.

FIG. 2 is a circuit diagram of a memory cell array included in the semiconductor memory device according to the first embodiment.

FIG. 3 is a cross-sectional view of a memory cell array included in the semiconductor memory device according to the first embodiment.

FIG. 4 is a diagram illustrating threshold voltage distributions and data allocation in a case where each memory cell included in the semiconductor memory device is a triple level cell (TLC) capable of storing 3-bit (8-value) data according to the first embodiment.

FIG. 5 is a diagram illustrating a writing order of data in a NAND string included in the semiconductor memory device according to the first embodiment.

FIG. 6 is a diagram illustrating an example of a relationship among a state of a channel of a memory pillar including a selected memory cell as a program target, a voltage of each interconnect, and a band diagram of the channel during a program operation executed in the semiconductor memory device according to the first embodiment.

FIG. 7 is a diagram illustrating an example of a relationship between a state of a channel of a memory pillar including a program-inhibited selected memory cell and a voltage of each interconnect during a program operation executed in the semiconductor memory device according to the first embodiment.

FIG. 8 is a diagram illustrating an example of a state of each transistor in a NAND string during a program operation executed in the semiconductor memory device according to the first embodiment.

FIG. 9 is a graph showing an example of a relationship between a current flowing through a switch memory cell included in the semiconductor memory device and a voltage of a switch word line according to the first embodiment.

FIG. 10 is a timing chart illustrating an example of a voltage of each interconnect during a program operation executed by the semiconductor memory device according to the first embodiment.

FIG. 11 is a diagram illustrating an example of a relationship between a state of a channel of a memory pillar including a selected memory cell as a program target and a voltage of each interconnect during a program operation executed in a semiconductor memory device according to a first modification of the first embodiment.

FIG. 12 is a diagram illustrating an example of a relationship between a state of a channel of a memory pillar including a selected memory cell as a program target and a voltage of each interconnect during a program operation executed in a semiconductor memory device according to a second modification of the first embodiment.

FIG. 13 is a diagram illustrating an example of a relationship among a state of a channel of a memory pillar including a selected memory cell as a program target, a voltage of each interconnect, and a band diagram of the channel during a program operation executed in a semiconductor memory device according to a second embodiment.

FIG. 14 is a diagram illustrating an example of a relationship between a state of a channel of a memory pillar including a program-inhibited selected memory cell and a voltage of each interconnect during a program operation executed in the semiconductor memory device according to the second embodiment.

FIG. 15 is a diagram illustrating an example of a state of each transistor in a NAND string during a program operation executed in the semiconductor memory device according to the second embodiment.

FIG. 16 is a timing chart showing an example of a voltage of each interconnect during a program operation executed by the semiconductor memory device according to the second embodiment.

### DETAILED DESCRIPTION

In general, according to one embodiment, a semiconductor memory device includes a first memory string, a bit line, a source line, a first select gate line, a second select gate line, a first word line, a second word line, a third word line, and a control circuit. The first memory string includes a first selection transistor, a first memory cell, a second memory cell, a third memory cell, and a second selection transistor in which current paths are coupled in series. The bit line is coupled to the first selection transistor. The source line is coupled to the second selection transistor. The first select gate line is coupled to a gate of the first selection transistor. The second select gate line is coupled to a gate of the second selection transistor. The first word line is coupled to a gate of the first memory cell. The second word line is coupled to a gate of the second memory cell. The third word line is coupled to a gate of the third memory cell. The control circuit is configured to execute a write operation including a program operation and a program verify operation. In a case where data is written to the first memory cell in the program operation of the first memory cell, the control circuit is configured to apply a first voltage to the bit line BL, apply a second voltage lower than the first voltage to the source line, apply a third voltage higher than the first voltage to the first select gate line, apply a fourth voltage higher than the first voltage to the second select gate line, apply a program voltage to the first word line, apply a fifth voltage to the second word line, and apply a sixth voltage higher than the fifth voltage and lower than the program voltage to the third word line.

Hereinafter, embodiments will be described with reference to the drawings. Note that, in the following description, components having the same function and configuration are denoted by the same reference numerals. In addition, in a case where a plurality of components having a common reference sign is distinguished, the common reference sign is added with a suffix to be distinguished. Note that, in a case where a plurality of components does not need to be particularly distinguished, only common reference numerals are attached to the plurality of components, and no suffixes are attached thereto. Here, the suffix is not limited to a subscript or a superscript, and includes, for example, a lowercase alphabet added to the end of the reference sign, an index meaning an array, and the like.

### 1. First Embodiment

A semiconductor memory device 1 according to a first embodiment will be described. The semiconductor memory device 1 is a NAND flash memory capable of storing data in a nonvolatile manner. Note that the semiconductor memory device 1 is not limited to the NAND flash memory. The semiconductor memory device 1 may be another non-volatile memory.

### 1.1 Configuration

### 1.1.1 Overall Configuration of Semiconductor Memory Device

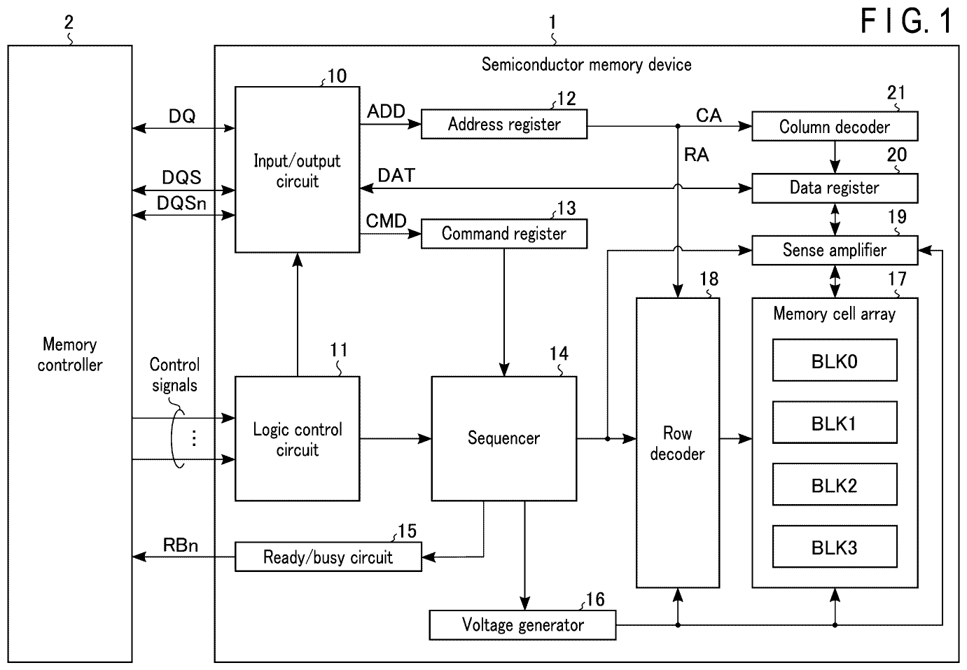

First, an example of an overall configuration of the semiconductor memory device 1 will be described with reference to FIG. 1. FIG. 1 is a block diagram illustrating the overall configuration of the semiconductor memory device 1. Note that, in the example shown in FIG. 1, some of the couplings between the constituent elements are indicated by arrow lines. Needless to say, the couplings between the constituent elements are not limited to the example shown in FIG. 1.

As illustrated in FIG. 1, the semiconductor memory device 1 is configured to be controllable by an external memory controller 2. For example, the semiconductor memory device 1 transmits and receives a signal DQ and timing signals DQS and DQSn to and from the memory controller 2. The signal DQ is, for example, data DAT, address ADD, or command CMD. The timing signals DQS and DQSn are timing signals used at the time of input and output of the data DAT. The timing signal DQSn is an inverted signal of the timing signal DQS.

In addition, the semiconductor memory device 1 receives various control signals from the memory controller 2. Then, the semiconductor memory device 1 transmits a ready/busy signal RBn to the memory controller 2. The ready/busy signal RBn is a signal indicating whether the semiconductor memory device 1 is in a state (busy state) in which the semiconductor memory device 1 cannot receive the command CMD from the memory controller 2 or in a state (ready state) in which the semiconductor memory device 1 can receive the command CMD from the memory controller 2.

The semiconductor memory device 1 includes an input/output circuit 10, a logic control circuit 11, an address register 12, a command register 13, a sequencer 14, a ready/busy circuit 15, a voltage generator 16, a memory cell array 17, a row decoder 18, a sense amplifier 19, a data register 20, and a column decoder 21.

The input/output circuit 10 is a circuit that inputs and outputs the signal DQ. The input/output circuit 10 is coupled to the memory controller 2. In addition, the input/output circuit 10 is coupled to the logic control circuit 11, the address register 12, the command register 13, and the data register 20.

In a case where the input signal DQ is the address ADD, the input/output circuit 10 transmits the address ADD to the address register 12. In addition, in a case where the input signal DQ is the command CMD, the input/output circuit 10 transmits the command CMD to the command register 13.

In a case where the input signal DQ is the data DAT, the input/output circuit 10 receives the input signal DQ based on the timing signals DQS and DQSn. Then, the input/output circuit 10 transmits the data DAT to the data register 20. In addition, the input/output circuit 10 outputs the data DAT as the output signal DQ to the memory controller 2 together with the timing signals DQS and DQSn.

The logic control circuit 11 is a circuit that performs logic control based on control signals. The logic control circuit 11 is coupled to the memory controller 2. In addition, the logic control circuit 11 is coupled to the input/output circuit 10 and the sequencer 14. The logic control circuit 11 receives a plurality of control signals from the memory controller 2. The logic control circuit 11 controls the input/output circuit 10 and the sequencer 14 based on the received control signals.

The address register 12 is a register that temporarily stores the address ADD. The address register 12 is coupled to the input/output circuit 10, the row decoder 18, and the column decoder 21. The address ADD includes a row address RA and a column address CA. The row address RA is an address for selecting interconnects (word lines and select gate lines) arranged in a row direction in the memory cell array 17. The column address CA is an address for selecting interconnects (bit lines) arranged in a column direction in the memory cell array 17. For example, the row address RA includes a block address and a word line address. The block address is an address designating any of a plurality of blocks BLK included in the memory cell array 17. The word line address is an address designating any of a plurality of word lines coupled to the block BLK.

The address register 12 transfers the row address RA to the row decoder 18. Further, the address register 12 transfers the column address CA to the column decoder 21.

The command register 13 is a register that temporarily stores the command CMD. The command register 13 is coupled to the input/output circuit 10 and the sequencer 14. The command register 13 transfers the command CMD to the sequencer 14.

The sequencer 14 is a control circuit that controls the semiconductor memory device 1. The sequencer 14 controls the entire operation of the semiconductor memory device 1. For example, the sequencer 14 controls the ready/busy circuit 15, the voltage generator 16, the row decoder 18, the sense amplifier 19, the data register 20, and the column decoder 21. For example, the sequencer 14 executes a write operation, a read operation, an erase operation, and the like based on the command CMD.

The ready/busy circuit 15 is a circuit that transmits the ready/busy signal RBn to the memory controller 2 based on the control of the sequencer 14.

The voltage generator 16 generates voltages used for the write operation, the read operation, and the erase operation based on the control of the sequencer 14. The voltage generator 16 supplies the generated voltages to the memory cell array 17, the row decoder 18, the sense amplifier 19, and the like. The row decoder 18 and the sense amplifier 19 may apply the voltages supplied from the voltage generator 16 to the memory cell array 17.

The memory cell array 17 is a set of a plurality of memory cells (also referred to as “memory cell transistors”) arranged in a matrix. The memory cell array 17 includes the plurality of blocks BLK. In the example illustrated in FIG. 1, the memory cell array 17 includes four blocks BLK0, BLK1, BLK2, and BLK3. The number of blocks BLK in the memory cell array 17 is arbitrary. The block BLK is, for example, a set of a plurality of memory cells from which data is collectively erased. That is, the block BLK is a data erasing unit. Details of the configuration of the block BLK will be described later.

The row decoder 18 is a decode circuit of the row address RA. The row decoder 18 selects any block BLK in the memory cell array 17 based on the decoding result. The row decoder 18 applies voltages to interconnects (word lines and select gate lines) in the row direction of the selected block BLK.

The sense amplifier 19 is a circuit that writes and reads the data DAT. The sense amplifier 19 is coupled to the memory cell array 17 and the data register 20. The sense amplifier 19 reads the data DAT from the memory cell array 17 during the read operation. In addition, the sense amplifier 19 supplies voltages based on the write data DAT to the memory cell array 17 during the write operation.

The data register 20 is a register that temporarily stores the data DAT. The data register 20 is coupled to the sense amplifier 19 and the column decoder 21. The data register 20 includes a plurality of latch circuits. Each latch circuit temporarily stores write data or read data.

The column decoder 21 is a circuit that decodes the column address CA. The column decoder 21 receives the column address CA from the address register 12. The column decoder 21 selects the latch circuit in the data register 20 based on the decoding result of the column address CA.

### 1.1.2 Circuit Configuration of Memory Cell Array

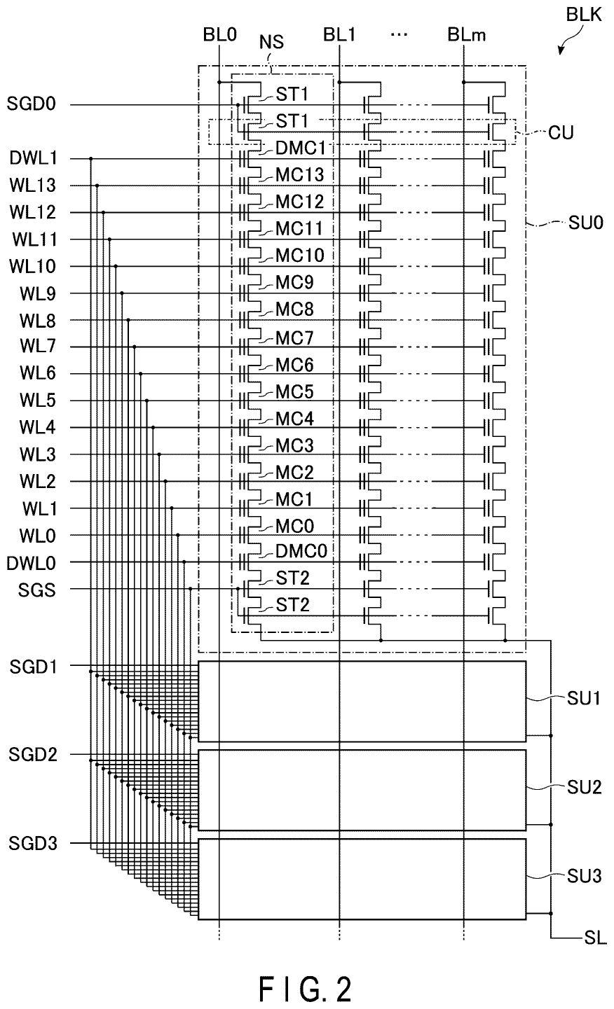

Next, an example of a circuit configuration of the memory cell array 17 will be described with reference to FIG. 2. FIG. 2 is a circuit diagram of the memory cell array 17. FIG. 2 illustrates an example of a circuit configuration of one block BLK included in the memory cell array 17. The other blocks BLK also have the same configuration as that of FIG. 2.

The block BLK includes, for example, four string units SU0 to SU3. Note that the number of string units SU included in the block BLK is arbitrary. A string unit SU is, for example, a set of a plurality of NAND strings NS collectively selected in the write operation or the read operation.

The string unit SU includes a plurality of NAND strings NS. The NAND string NS includes a set of a plurality of memory cells coupled in series. Each of the plurality of NAND strings NS in the string unit SU is coupled to any of bit lines BLO to BLm (m is an integer of 1 or more).

The NAND string NS includes a plurality of memory cells MC, a plurality of dummy memory cells DMC, one or more selection transistors ST1, and one or more selection transistors ST2. The number of memory cells MC and the number of dummy memory cells DMC are arbitrary. The dummy memory cell DMC may not be provided. In the example illustrated in FIG. 2, the NAND string NS includes 14 memory cells MC0 to MC13, two dummy memory cells DMC0 and DMC1, two selection transistors ST1, and two selection transistors ST2.

The memory cell MC is a memory element that stores data in a nonvolatile manner. The dummy memory cell DMC has the same configuration as the memory cell MC, but is used as a dummy and is not used for storing data.

The memory cell MC and the dummy memory cell DMC include a control gate and a charge storage layer. The memory cell MC and the dummy memory cell DMC may be of a metal-oxide-nitride-oxide-silicon (MONOS) type using an insulator for the charge storage layer, or may be of a floating gate (FG) type using a conductor for the charge storage layer. Hereinafter, a case where the memory cell MC and the dummy memory cell DMC are of the MONOS type will be described.

The selection transistors ST1 and ST2 are switching elements. The selection transistors ST1 and ST2 are used to select the string units SU during various operations, respectively. The number of selection transistors ST1 and ST2 is arbitrary, and may be one or more.

In the example illustrated in FIG. 2, in the NAND string NS, current paths of the two selection transistors ST2, the dummy memory cell DMC0, the memory cells MC0 to MC13, the dummy memory cell DMC1, and the two selection transistors ST1 are coupled in series in order from a source line SL side. A drain of the selection transistor ST1 located at one end of the NAND string NS is coupled to the bit line BL. A source of the selection transistor ST2 located at the other end of the NAND string NS is coupled to the source line SL.

Control gates of the memory cells MC0 to MC13 of the same block BLK are commonly coupled to the word lines WL0 to WL13, respectively. More specifically, for example, the block BLK includes the four string units SU0 to SU3. Each string unit SU includes a plurality of memory cells MC0. Control gates of the plurality of memory cells MC0 in the block BLK are commonly coupled to one word line WL0. The same applies to the memory cells MCi to MC13.

Similarly to the memory cell MC, the control gates of the dummy memory cells DMC0 and DMC1 of the same block BLK are commonly coupled to the dummy word lines DWL0 and DWL1, respectively.

Gates of the plurality of selection transistors ST1 in the string unit SU are commonly coupled to one select gate line SGD. More specifically, gates of the plurality of selection transistors ST1 in the string unit SU0 are commonly coupled to a select gate line SGD0. Gates of the plurality of selection transistors ST1 in the string unit SU1 are commonly coupled to a select gate line SGD1. Gates of the plurality of selection transistors ST1 in the string unit SU2 are commonly coupled to a select gate line SGD2. Gates of the plurality of selection transistors ST1 in the string unit SU3 are commonly coupled to a select gate line SGD3.

Gates of the plurality of selection transistors ST2 in the block BLK are commonly coupled to a select gate line SGS. Like the select gate line SGD, the select gate line SGS may be provided for each string unit SU.

The word lines WL0 to WL13, the dummy word lines DWL0 and DWL1, the select gate lines SGD0 to SGD3, and the select gate line SGS are coupled to the row decoder 18.

The bit line BL is commonly coupled to one NAND string NS in each string unit SU of each block BLK. Each bit line BL is coupled to the sense amplifier 19.

The source line SL is shared among the plurality of blocks BLK, for example.

A set of the plurality of memory cells MC coupled to the common word line WL in one string unit SU is referred to as, for example, “cell unit CU”. In other words, the cell unit CU is a set of a plurality of memory cells MC collectively selected in the write operation or the read operation. A page is a unit of data that is collectively written (or collectively read) to the cell unit CU. For example, in a case where the memory cell MC stores 1-bit data, a storage capacity of the cell unit CU is one page. The cell unit CU can have the storage capacity of two or more pages based on the number of bits of data stored in the memory cell MC.

### 1.1.3 Cross-Sectional Structure of Memory Cell Array

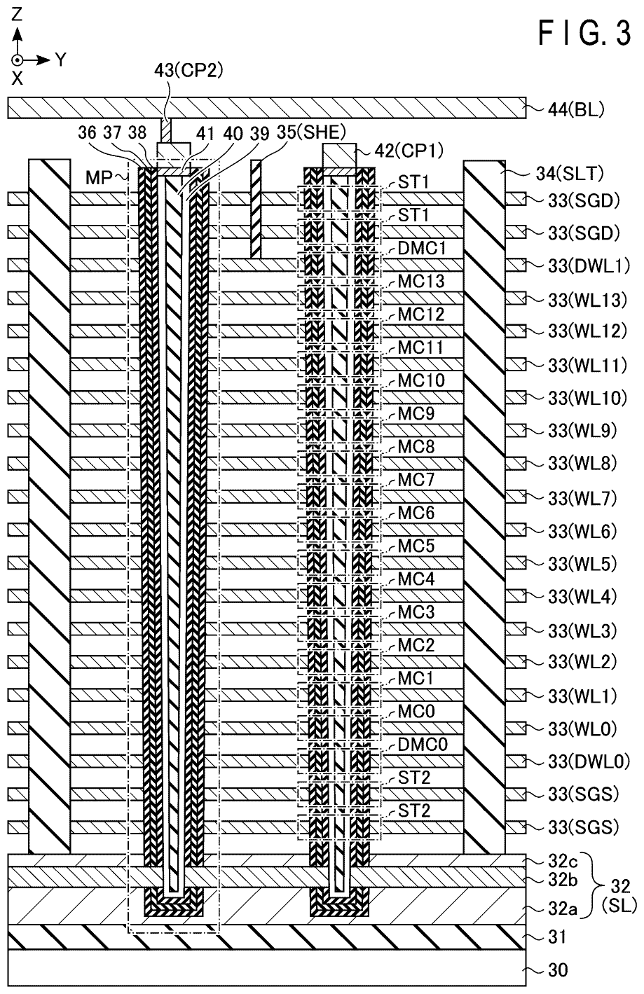

Next, an example of a cross-sectional structure of the memory cell array 17 will be described with reference to FIG. 3. FIG. 3 is a cross-sectional view of the memory cell array 17. In the example illustrated in FIG. 3, a part of the insulating layer is omitted.

In the following description, a direction perpendicular to a surface of a semiconductor substrate 30 is referred to as a Z direction. A direction which intersects with the Z direction and in which the word line WL extends is referred to as an X direction. A direction which intersects with the X direction and the Z direction and in which the bit line BL extends is defined as a Y direction.

As illustrated in FIG. 3, an insulating layer 31 is provided on the semiconductor substrate 30. The insulating layer 31 includes, for example, silicon oxide (SiO). Note that a circuit such as the row decoder 18 or the sense amplifier 19 may be provided in a region below the memory cell array 17 where the insulating layer 31 is formed, that is, between the semiconductor substrate 30 and a semiconductor layer 32. The semiconductor layer 32 functioning as the source line SL is formed on the insulating layer 31.

The semiconductor layer 32 includes, for example, three semiconductor layers 32a, 32b, and 32c. The semiconductor layer 32a is provided on the insulating layer 31. The semiconductor layer 32b is provided on the semiconductor layer 32a. The semiconductor layer 32c is provided on the semiconductor layer 32b. The semiconductor layer 32b is formed, for example, by replacing a sacrificial layer provided between the semiconductor layer 32a and the semiconductor layer 32c. The semiconductor layers 32a to 32c include, for example, silicon. In addition, the semiconductor layers 32a to 32c include, for example, phosphorus (P) as an impurity of the semiconductor. Note that the above-described structure of the source line SL is an example. The structure of the source line SL is not limited to the above-described structure. For example, the source line SL may be formed of a single semiconductor layer 32. For example, the semiconductor layer 32 may be eliminated, and the semiconductor substrate 30 may function as the source line SL.

Above the semiconductor layer 32, 20 interconnect layers 33 are provided spaced apart in the Z direction. The 20 interconnect layers 33 function as two select gate lines SGS, a dummy word line DWL0, word lines WL0 to WL13, a dummy word line DWL1, and two select gate lines SGD in this order from the semiconductor layer 32 side. The interconnect layer 33 extends in the X direction. As the conductive material of the interconnect layers 33, for example, a stacked structure of titanium nitride (TiN)/tungsten (W) is used. In this case, titanium nitride is formed so as to cover tungsten. Titanium nitride has a function as a barrier layer for suppressing oxidation of tungsten or an adhesion layer for improving adhesion of tungsten in a case where tungsten is deposited by, for example, chemical vapor deposition (CVD). In addition, the interconnect layer 33 may include a high dielectric constant material such as aluminum oxide (AlO). In this case, the high dielectric constant material is formed so as to cover the conductive material. For example, in each of the interconnect layers 33, a high dielectric constant material is provided so as to cover upper and lower sides of the interconnect layer 33 and side surfaces of memory pillars MP. Titanium nitride is provided so as to be in contact with the high dielectric constant material. Then, tungsten is provided so as to be in contact with titanium nitride and fill the inside of the interconnect layer 33. For example, in a case where aluminum oxide is provided as the high dielectric constant material, the memory cell MC is also referred to as a metal-aluminum-nitride-oxide-silicon (MANOS) type.

The interconnect layer 33 is separated for each block BLK, for example, by a slit SLT extending in the X direction. A bottom surface of the slit SLT is in contact with the semiconductor layer 32. For example, the slit SLT is embedded by an insulating layer 34. The insulating layer 34 includes, for example, silicon oxide. Note that a conductive material may be provided in the slit SLT so as to be in contact with the semiconductor layer 32 on the bottom surface of the slit SLT and not to be in contact with the interconnect layer 33 on the side surface of the slit.

The two uppermost interconnect layers 33 functioning as the select gate lines SGD are further separated in the Y direction for each string unit SU by a slit SHE extending in the X direction, for example. In the example illustrated in FIG. 3, one slit SHE is provided between the two slits SLT. That is, the example illustrated in FIG. 3 illustrates a case where two string units SU are included in one block BLK. The inside of the slit SHE is embedded by the insulating layer 35. For example, the insulating layer 35 includes silicon oxide.

In the Y direction, a plurality of memory pillars MP extending in the Z direction are arranged along the X direction between the two slits SLT. Note that the arrangement of the memory pillars MP between the two slits SLT is arbitrary. For example, the arrangement of the memory pillars MP may be a staggered arrangement of four, eight, or 16 rows in the X direction. One memory pillar MP corresponds to one NAND string NS. For example, the memory pillar MP has a substantially cylindrical shape extending in the Z direction. The memory pillar MP penetrates the 20 interconnect layers 33. The bottom surface of the memory pillar MP reaches the semiconductor layer 32.

The memory pillar MP includes a block insulating film 36, a charge storage layer 37, a tunnel insulating film 38, a semiconductor layer 39, a core layer 40, and a cap film 41. The block insulating film 36 and the core layer 40 include, for example, silicon oxide. The tunnel insulating film 38 includes, for example, silicon oxynitride (SiON). The tunnel insulating film 38 may include silicon oxide. The charge storage layer 37 includes, for example, silicon nitride (SiN). The semiconductor layer 39 and the cap film 41 include, for example, silicon.

On a part of the side surface and the bottom surface of the memory pillar MP, a block insulating film 36, a charge storage layer 37, and a tunnel insulating film 38 are laminated in this order from the outer periphery. More specifically, in the same layer of the semiconductor layer 32b and the vicinity thereof, the block insulating film 36, the charge storage layer 37, and the tunnel insulating film 38 on the side surface of the memory pillar MP are removed. The semiconductor layer 39 is provided so as to be in contact with the side surface and the bottom surface of the tunnel insulating film 38 and the semiconductor layer 32b. The semiconductor layer 39 is a region in which channels of the memory cell MC, the dummy memory cell DMC, and the selection transistors ST1 and ST2 are formed. Therefore, the semiconductor layer 39 functions as a signal line that couples current paths of the selection transistor ST2, the dummy memory cell DMC0, the memory cells MC0 to MC13, the dummy memory cell DMC1, and the selection transistor ST1. The inside of the semiconductor layer 39 is embedded by the core layer 40. Note that the structure of the memory pillar MP described above is an example. The structure of the memory pillar MP is not limited to the above. For example, the block insulating film 36, the charge storage layer 37, and the tunnel insulating film 38 may be provided on the side surface of the memory pillar MP, and the block insulating film 36, the charge storage layer 37, and the tunnel insulating film 38 on the bottom surface of the memory pillar MP may be removed. In this case, the semiconductor layer 39 and the semiconductor layer 32 (source line SL) are in contact with each other on the bottom surface of the memory pillar MP.

In the upper portion of the memory pillar MP, the cap film 41 is provided on upper ends of the semiconductor layer 39 and the core layer 40. The side surface of the cap film 41 is in contact with the tunnel insulating film 38.

The memory pillar MP and the 14 interconnect layers 33 functioning as the word lines WL0 to WL13 configure the memory cells MC0 to MC13, respectively. Similarly, the memory pillar MP and the two interconnect layers 33 respectively functioning as the dummy word lines DWL0 and DWL1 configure the dummy memory cells DMC0 and DMC1, respectively. The memory pillar MP and the interconnect layer 33 functioning as the select gate line SGD configure the selection transistor ST1. The memory pillar MP and the interconnect layer 33 functioning as the select gate line SGS configure the selection transistor ST2. In the example illustrated in FIG. 3, two interconnect layers 33 functioning as each of the select gate lines SGD and SGS are provided, but one or more interconnect layers may be provided.

A conductor 42 functioning as a contact plug CP1 is provided on the cap film 41. A conductor 43 functioning as a contact plug CP2 is provided on the conductor 42. For example, the conductors 42 and 43 have a substantially cylindrical shape extending in the Z direction. The conductors 42 and 43 include, for example, a metal material such as copper (Cu) or tungsten as a conductive material.

A interconnect layer 44 functioning as the bit line BL is provided on the conductor 43. The interconnect layer 44 extends in the Y direction. The interconnect layer 44 includes, for example, copper as a conductive material.

### 1.2 Threshold Voltage Distribution of Memory Cell

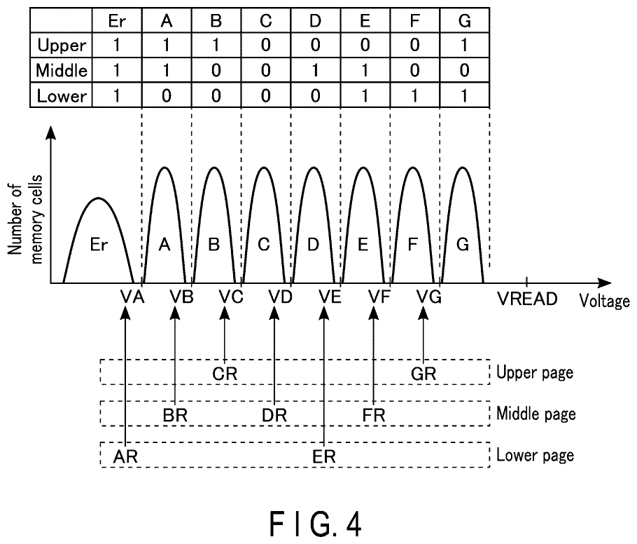

Next, an example of threshold voltage distributions that can be taken by the memory cell MC will be described with reference to FIG. 4. FIG. 4 is a diagram illustrating threshold voltage distributions and data allocation in a case where each memory cell MC is a triple level cell (TLC) capable of storing 3-bit (8-value) data. The number of bits of data that can be stored in the memory cell MC is arbitrary. For example, the memory cell MC may be a single level cell (SLC) capable of storing 1-bit (binary) data or a multi level cell (MLC) capable of storing 2-bit (four-value) data. Further, the memory cell MC may be a quad level cell (QLC) capable of storing 4-bit (16 value) data or a penta level cell (PLC) capable of storing 5-bit (32 value) data.

As illustrated in FIG. 4, in a case where the memory cell MC is the TLC, the threshold voltage of each memory cell MC takes a value included in any of discrete, for example, eight distributions. Hereinafter, the eight distributions are referred to as an “Er” state, an “A” state, a “B” state, a “C” state, a “D” state, an “E” state, an “F” state, and a “G” state in ascending order of the threshold voltage.

The “Er” state corresponds to, for example, a data erase state. Then, “A” to “G” states correspond to states in which charges are injected into the charge storage layer 37 and data is written. In the write operation, verify voltages corresponding to the threshold voltage distributions are VA to VG. Then, these voltage values have a relationship of VA<VB<VC<VD<VE<VF<VG<VREAD. The voltage VREAD is a voltage applied to the unselected word line WL during the read operation. In a case where the voltage VREAD is applied to the gate of the memory cell MC, the memory cell MC is turned on regardless of stored data. In the following description, the word line WL selected during the write operation or the read operation is referred to as a “selected word line WL”, and the word line WL not selected during the write operation or the read operation is referred to as a “unselected word line WL”.

More specifically, the threshold voltage included in the “Er” state is lower than the voltage VA. The threshold voltage included in the “A” state is equal to or higher than the voltage VA and lower than the voltage VB. The threshold voltage included in the “B” state is equal to or higher than the voltage VB and lower than the voltage VC. The threshold voltage included in the “C” state is equal to or higher than the voltage VC and lower than the voltage VD. The threshold voltage included in the “D” state is equal to or higher than the voltage VD and lower than the voltage VE. The threshold voltage included in the “E” state is equal to or higher than the voltage VE and lower than the voltage VF. The threshold voltage included in the “F” state is equal to or higher than the voltage VF and lower than the voltage VG. The threshold voltage included in the “G” state is equal to or higher than the voltage VG and lower than the voltage VREAD.

The set value of the verify voltage and the set value of the read voltage corresponding to each state may be the same or different.

Hereinafter, the read operation corresponding to the “A” to “G” states will be referred to as an AR read operation, a BR read operation, a CR read operation, a DR read operation, an ER read operation, an FR read operation, and a GR read operation, respectively. In the AR read operation, it is determined whether or not the threshold voltage of the memory cell MC is lower than the voltage VA. In the BR read operation, it is determined whether or not the threshold voltage of the memory cell MC is lower than the voltage VB. In the CR read operation, it is determined whether or not the threshold voltage of the memory cell MC is lower than the voltage VC. The same applies to the DR read operation, the ER read operation, the FR read operation, and the GR read operation.

As described above, each memory cell MC has any one of the eight threshold voltage distributions, so that eight types of states can be taken. These states are allocated to “000” to “111” in binary notation, so that each memory cell MC can hold 3-bit data. Hereinafter, 3-bit data is referred to as a lower bit, a middle bit, and an upper bit, respectively. Further, a set of lower bits collectively written (or read) to the cell unit CU is referred to as a lower page, a set of middle bits is referred to as a middle page, and a set of upper bits is referred to as an upper page.

In the example of FIG. 4, data is allocated to “upper bit/middle bit/lower bit” for the memory cell MC included in each threshold voltage distribution as follows.
“Er” state: “111” data
“A” state: “110” data
“B” state: “100” data
“C” state: “000” data
“D” state: “010” data
“E” state: “011” data
“F” state: “001” data
“G” state: “101” data

In the case of reading the data allocated in this manner, the lower bit is determined by the AR read operation and the ER read operation. The middle bit is determined by the BR read operation, the DR read operation, and the FR read operation. The Upper bit is determined by the CR read operation and the GR read operation. That is, the values of the lower bit, the middle bit, and the upper bit are determined by two, three, and two read operations, respectively. Hereinafter, this data allocation is referred to as “2-3-2 code”. Note that data allocation to the “Er” to “G” states is not limited to the 2-3-2 code.

### 1.3 Write Operation

Next, an example of the write operation will be described. The write operation includes a program operation and a program verify operation. The sequencer 14 increases the threshold voltage of the memory cell MC to a target level by repeating a combination of the program operation and the program verify operation (hereinafter, referred to as a “program loop”).

The program operation is an operation of injecting electrons into the charge storage layer 37 of the memory cell MC (hereinafter, also referred to as a “selected memory cell MC”) selected as a target of the write operation or inhibiting injection of electrons into the charge storage layer 37 based on the write data. With the injection of electrons into the charge storage layer 37, the threshold voltage of the selected memory cell MC increases. In other words, the program operation is an operation of increasing the threshold voltage or maintaining the threshold voltage of the selected memory cell MC based on the write data. Hereinafter, among the selected memory cells MC, the memory cell MC whose threshold voltage is increased is also referred to as a “selected memory cell MC as a program target”. Among the selected memory cells MC, the memory cell MC whose threshold voltage is not increased is also referred to as a “program-inhibited selected memory cell MC”.

In the program operation of the present embodiment, hot carriers are injected into the charge storage layer 37 of the selected memory cell MC as a program target. Hereinafter, the program operation using hot carrier injection is also referred to as “program operation with hot carrier injection (HCI) assist”.

More specifically, hot carriers, that is, high-temperature electrons are generated using at least one of the memory cells MC (hereinafter, also referred to as a “unselected memory cell MC”) that are not selected as a target of the write operation in the same NAND string NS as the selected memory cell MC. The generated electrons are injected into the charge storage layer 37 of the selected memory cell MC. With the execution of the program operation with the HCI assist, the voltage (program voltage) applied to the selected word line WL can be reduced as compared with a method using a Fowler-Nordheim (FN) tunnel current.

The program verify operation is an operation of reading data from the selected memory cell MC after the program operation and determining whether or not the threshold voltage of the selected memory cell MC has reached a target level. The selected memory cell MC as the program target for which the threshold voltage has reached the target level is inhibited from being programmed in the subsequent program loop.

### 1.3.1 Write Order

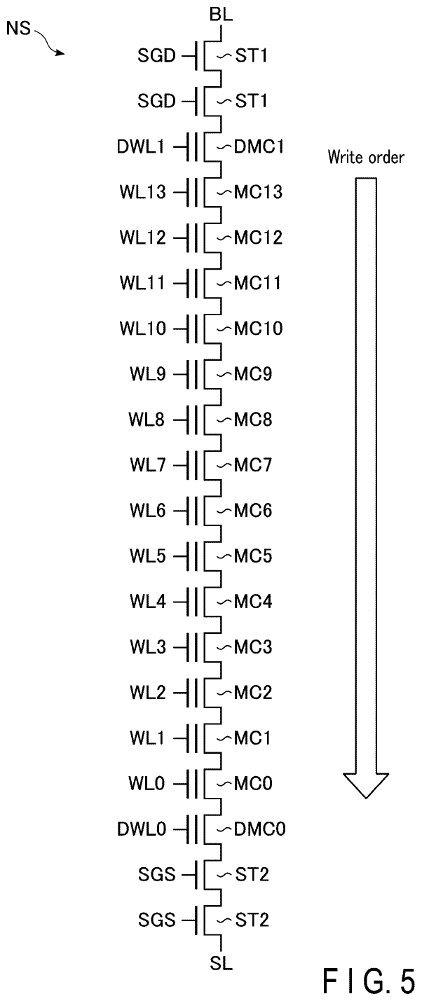

First, an example of the order of writing data in the NAND string NS will be described with reference to FIG. 5. FIG. 5 is a diagram illustrating the order of writing data in the NAND string NS.

As shown in FIG. 5, in a case where the write operation is executed, the memory cells MC on the bit line BL side (selection transistor ST1 side) are sequentially selected as the write target. Note that the memory cells MC on the source line SL side (selection transistor ST2 side) may be sequentially selected as the write target.

In the example illustrated in FIG. 5, the sequencer 14 first selects the word line WL13 and executes the write operation. Next, the sequencer 14 sequentially selects the word lines WL12 to WL1 and finally selects the word line WL0 to execute the write operation corresponding to each word line WL. In other words, the sequencer 14 first selects the memory cell MC13. Then, the sequencer 14 sequentially selects the memory cells MC12 to MCi and finally selects the memory cell MC0.

### 1.3.2 Program Operation

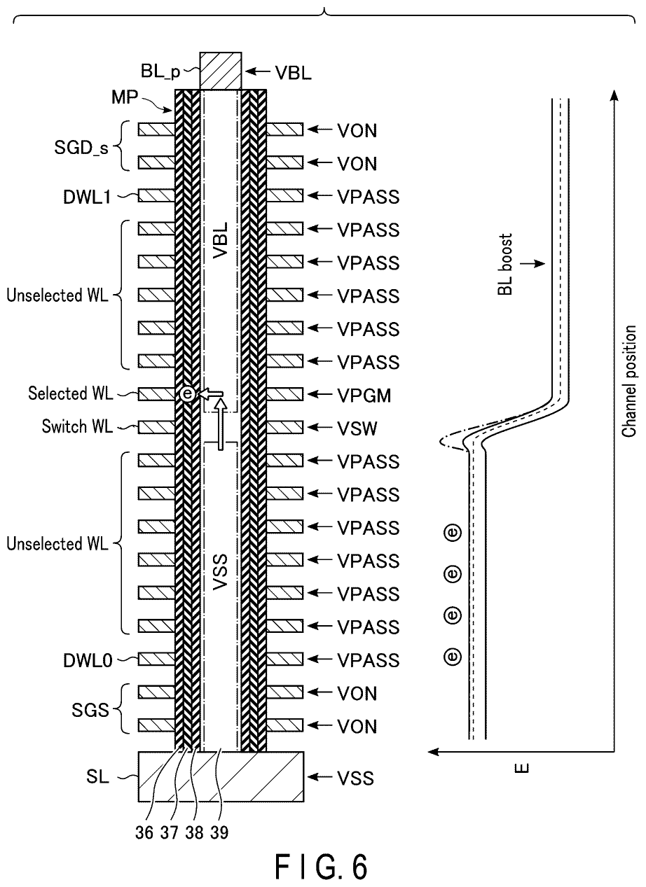

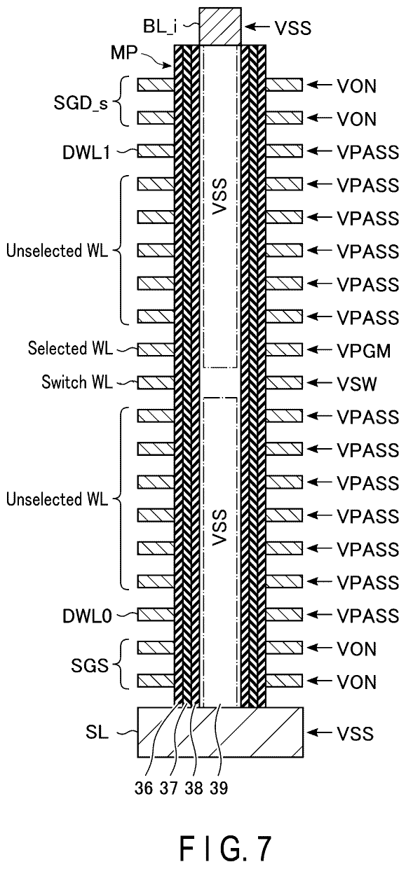

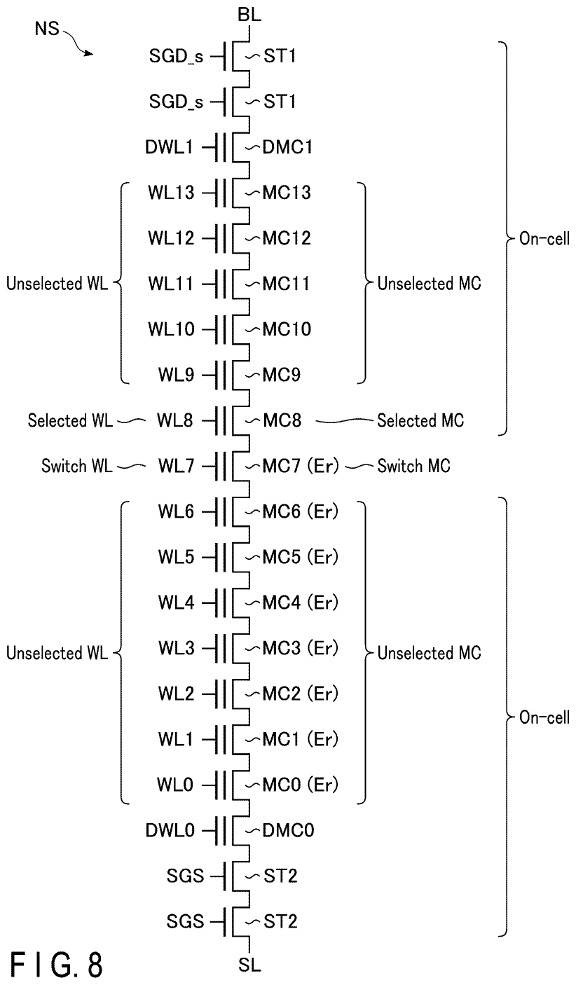

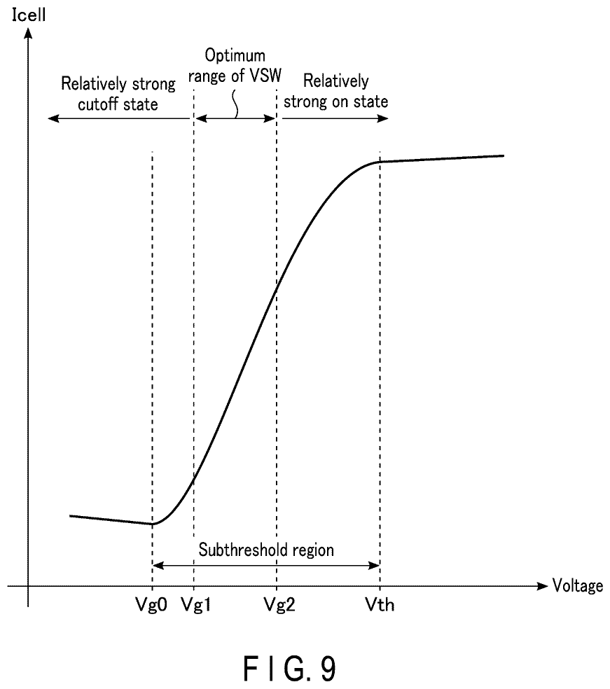

Next, an example of the program operation will be described with reference to FIGS. 6 to 9. FIG. 6 is a diagram illustrating an example of a relationship among a state of a channel of the memory pillar MP including the selected memory cell MC as a program target, the voltage of each interconnect, and a band diagram of the channel during the program operation. FIG. 7 is a diagram illustrating an example of a relationship between the state of the channel of the memory pillar MP including the program-inhibited selected memory cell MC and the voltage of each interconnect during the program operation. FIG. 8 is a diagram illustrating an example of a state of each transistor in the NAND string NS during the program operation. FIG. 9 is a graph illustrating an example of a relationship between a current Icell flowing through the switch memory cell MC and a voltage VSW of the switch word line WL.

In the following description, the string unit SU selected as a target of the write operation is referred to as a “selected string unit SU”. The select gate line SGD corresponding to the selected string unit SU is referred to as a “select gate line SGD_s”. The string units SU that are not selected as the target of the write operation are referred to as “unselected string units SU”. The select gate line SGD corresponding to the unselected string unit SU is referred to as a “select gate line SGD_u”. The bit line BL corresponding to the selected memory cell MC as a program target is referred to as a “bit line BL_p”. The bit line BL corresponding to the program-inhibited selected memory cell MC is referred to as a “bit line BL_i”.

As shown in FIGS. 6 and 7, in the present embodiment, the switch word line WL (switch WL) is provided separately from the selected word line WL (selected WL) and the unselected word line WL (unselected WL) in the program operation. The switch word line WL is an unselected word line WL coupled to the memory cell MC that generates hot carriers. In the memory cell MC (hereinafter, also referred to as a “switch memory cell MC”) corresponding to the switch word line WL, an electric field (potential difference) is formed between a drain and a source, and an appropriate voltage is applied to the switch word line WL, thereby generating hot carriers (HC).

For example, in a case where the write operation is sequentially executed from the memory cell MC on the bit line BL side, the switch word line WL is selected from the unselected word lines WL located on the source line SL side from the selected word line WL. The switch word line WL may be adjacent to or not adjacent to the selected word line WL. In addition, a plurality of adjacent unselected word lines WL may be selected as the switch word lines WL. In a case where the word line WL0 is the selected word line WL, at least one of the dummy word line DWL0 arranged on the source line SL side or the plurality of select gate lines SGS can be selected as the switch word line WL.

As illustrated in FIG. 6, during the program operation, the sense amplifier 19 applies a voltage VBL to a bit line BL_p. The voltage VBL is higher than a voltage (for example, a ground voltage VSS) applied to the source line SL. The voltage VBL is preferably set to a voltage higher by 1 V or more than the voltage VSS applied to the source line SL. As a result, in the switch memory cell MC, a relatively strong electric field for generating hot carriers can be generated in the extending direction of the semiconductor layer 39, that is, the extending direction of the channel. In other words, an electric field can be generated between the drain and the source of the switch memory cell MC. On the other hand, as illustrated in FIG. 7, in order not to generate hot carriers, the sense amplifier 19 applies the same voltage VSS as the source line SL to a bit line BL_i.

As illustrated in FIGS. 6 and 7, the voltage VSS is applied to the source line SL. The row decoder 18 applies a voltage VON to select gate lines SGD_s and the select gate lines SGS. The voltage VON is a positive voltage for turning on the selection transistors ST1 and ST2. The voltage VON is higher than the voltage VBL. The row decoder 18 applies a voltage VPASS to the unselected word line WL and the dummy word lines DWL0 and DWL1. The voltage VPASS is a voltage that turns on the memory cell MC and the dummy memory cell DMC regardless of the threshold voltage thereof. The voltage VPASS is higher than the voltage VBL. The voltage VPASS may be the same voltage value as or different from the voltage VON. The row decoder 18 applies a voltage VPGM to the selected word line WL. The voltage VPGM is a program voltage for injecting electrons into the charge storage layer of the selected memory cell MC as the program target. The voltage VPGM is a voltage higher than the voltage VPASS. Note that the voltage VPGM can be stepped up every time the program loop is repeated. The row decoder 18 applies the voltage VSW to the switch word line WL. The voltage VSW is lower than the voltage VPASS. Therefore, the voltage VPGM, the voltage VPASS, and the voltage VSW have a relationship of VPGM>VPASS>VSW. For example, the voltage VSW is set to a voltage value equal to or lower than the threshold voltage of the switch memory cell MC. More specifically, the voltage VSW is a voltage that brings the switch memory cell MC into a state of a subthreshold region close to a cutoff state.

As illustrated in FIG. 8, for example, the word line WL8 is selected as the selected word line WL. The word lines WL0 to WL6 and WL9 to WL13 are selected as the unselected word lines WL. The word line WL7 is selected as the switch word line WL. In this case, the unselected memory cell MC (unselected MC) located closer to the bit line BL than the selected memory cell MC (selected MC) has already written data. Therefore, the threshold voltages of the memory cells MC9 to MC13 are in any of states of “Er” to “G”. The switch memory cell MC (switch MC) and the unselected memory cells MC located closer to the source line SL than the selected memory cell MC are in an unwritten state. Therefore, the threshold voltages of the memory cells MC0 to MC7 are in an “Er” state (erase state). The switch word line WL is selected from the unselected word lines WL corresponding to the unselected memory cells MC in the “Er” state.

The voltage described with reference to FIGS. 6 and 7 is applied to the memory pillar MP. As a result, the selection transistors ST1 and ST2, the dummy memory cells DMC0 and DMC1, the unselected memory cells MC, and the selected memory cell MC are turned on. Hereinafter, the transistor in the on state is also referred to as an “on-cell”.

Next, referring back to FIG. 6, the state of the channel of the memory pillar MP will be described. In the band diagram of the channel of FIG. 6, a vertical axis E indicates the level of electron energy. The horizontal axis indicates a channel position.

In a case where the above-described voltages are applied to the memory pillar MP corresponding to the program target, the selection transistor ST1, the dummy memory cell DMC1, the unselected memory cells MC located on the bit line BL side from the selected memory cell MC, and the selected memory cell MC are in an on state. Therefore, a channel is formed in the semiconductor layer 39 from the end on the bit line BL side to the selected word line WL (selected memory cell MC). The potential of the channel on the bit line BL side rises to the same voltage VBL as the bit line BL_p.

In addition, the selection transistors ST2, the dummy memory cell DMC0, and the unselected memory cells MC located on the source line SL side from the switch memory cell MC are turned on. Therefore, a channel is formed in the semiconductor layer 39 from the end on the source line SL side to the unselected word line WL (unselected memory cell MC) that is adjacent to the switch word line WL in the source line SL side. The potential of the channel on the source line SL side is the same voltage VSS as the source line SL. In the region of the semiconductor layer 39 corresponding to the switch word line WL, an electric field of a potential difference (VBL-VSS) is generated in the extending direction of the channel. In other words, an electric field of a potential difference (VBL-VSS) is formed between the drain and the source of the switch memory cell MC.

Therefore, as in the band diagram of the channel illustrated in FIG. 6, the band (potential) is bent in a region corresponding to the switch word line WL (switch memory cell MC). In this state, the row decoder 18 applies the voltage VSW to the switch word line WL. As a result, electrons on the source line SL side are injected into the bit line BL side beyond a potential barrier indicated by a solid line. That is, hot carriers are generated. The electrons injected into the channel on the bit line BL side are injected into the charge storage layer 37 of the selected memory cell MC as the program target by a potential difference between the selected word line WL and the channel. In a case where the voltage VSW is not applied to the switch word line WL and the switch memory cell MC is in a cutoff state, the potential barrier from the source line SL side to the bit line BL side indicated by a one-dot chain line is larger than that indicated by a solid line.

As illustrated in FIG. 7, in a case where the above-described voltages are applied to the memory pillar MP corresponding to the program inhibition, the potential of the channel on the bit line BL side is the same voltage VSS as the bit line BL_i. Therefore, no electric field is formed between the drain and the source of the switch memory cell MC. That is, hot carriers are not generated. Therefore, electrons are not injected into the charge storage layer 37 of the program-inhibited selected memory cell MC.

Next, an optimum range of the voltage VSW for generating hot carriers will be described.

As illustrated in FIG. 9, a vertical axis of the graph represents a current Icell flowing through the memory pillar MP, that is, a current flowing between the drain and the source of the switch memory cell MC. The horizontal axis of the graph indicates the voltage applied to the switch word line WL, that is, the voltage applied to the control gate of the switch memory cell MC. A voltage Vth indicates a threshold voltage of the switch memory cell MC. For example, the voltage at which the current Icell starts to flow is Vg0. In this case, a region from the voltage Vg0 to the voltage Vth is a subthreshold region of the switch memory cell MC. The voltage VSW is set to a voltage higher than the voltage Vg0 and equal to or lower than the voltage Vth. A lower limit value of the optimum range of the voltage VSW is defined as a voltage Vg1, and an upper limit value thereof is defined as a voltage Vg2. The voltages Vg0, Vg1, Vg2, and Vth have a relationship of Vg0<Vg1<Vg2<Vth. In a case where the voltage VSW is lower than the voltage Vg1, the switch memory cell MC is in a relatively strong cutoff state. Therefore, a current does not sufficiently flow between the drain and the source of the switch memory cell MC. That is, the current Icell does not sufficiently flow. Therefore, no hot carriers are generated. In a case where the voltage VSW is higher than the voltage Vg2, the switch memory cell MC is turned on relatively strongly. Therefore, a channel is formed, and no hot carriers are generated.

Therefore, even if a voltage VSW outside the optimum range is applied to the switch word line WL, the threshold voltage of the selected memory cell MC cannot be efficiently changed.

### 1.3.3 Voltage of Each Interconnect During Program Operation

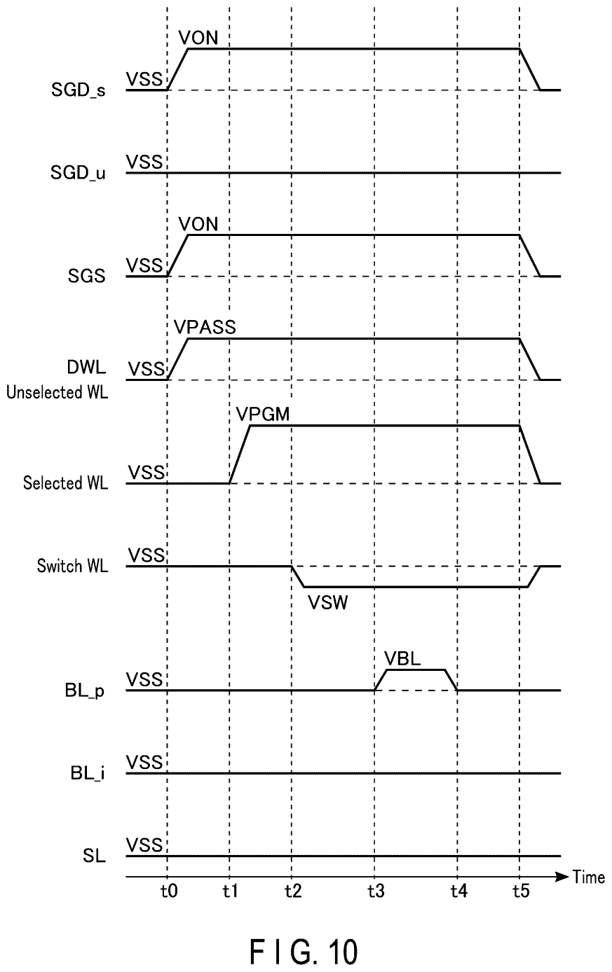

Next, an example of the voltage of each interconnect during the program operation will be described with reference to FIG. 10. FIG. 10 is a timing chart illustrating an example of the voltage of each interconnect during the program operation.

As illustrated in FIG. 10, first, at time t0, the row decoder 18 applies a voltage VON to the select gate lines SGD_s and the select gate lines SGS under the control of the sequencer 14. The select gate line SGD_s corresponds to the selected string unit SU. In addition, the row decoder 18 applies the voltage VPASS to the dummy word lines DWL and the unselected word lines WL. As a result, the selection transistors ST2, the selection transistors ST1 of the selected string unit SU, the dummy memory cells DMC, and the unselected memory cells MC are turned on. The row decoder 18 applies the voltage VSS to the select gate lines SGD_u corresponding to the unselected string units SU, the selected word line WL, and the switch word line WL. The selection transistors ST1 of the unselected string units SU are turned off. The sense amplifier 19 applies the voltage VSS to the bit lines BL_p and BL_i under the control of the sequencer 14. The voltage VSS is applied to the source line SL.

Next, at time t1, the row decoder 18 applies the voltage VPGM to the selected word line WL. As a result, the selected memory cell MC is turned on.

Next, at time t2, the row decoder 18 applies the voltage VSW to the switch word line WL. In the example illustrated in FIG. 10, a case where the voltage VSW is lower than the voltage VSS is illustrated, but the voltage VSW may not be a negative voltage.

Next, at time t3, the sense amplifier 19 applies the voltage VBL to the bit line BL_p. As a result, hot carriers (electrons) are generated in the switch memory cell MC corresponding to the program target. The generated electrons are injected into the charge storage layer 37 of the selected memory cell MC as the program target. During a period from time t3 to time t4, injection of electrons is executed.

Next, at time t4, the sense amplifier 19 applies the voltage VSS to the bit line BL_p.

Next, at time t5, the row decoder 18 applies the voltage VSS to the select gate lines SGD_s and SGS, the dummy word lines DWL, the unselected word lines WL, the selected word line WL, and the switch word line WL. As a result, the program operation ends.

In the example illustrated in FIG. 10, the case where the voltage VPGM is applied to the selected word line WL at the time t1, the voltage VSW is applied to the switch word line WL at the time t2, and the voltage VBL is applied to the bit line BL_p at the time t3 has been described. However, the order in which the voltages are applied to the selected word line WL, the switch word line WL, and the bit line BL_p is not limited thereto. For example, the voltage VSW may be applied to the switch word line WL after the voltage VBL is applied to the bit line BL_p.

### 1.4 Effects According to Present Embodiment

With the configuration according to the present embodiment, the semiconductor memory device can reduce power consumption. This effect will be described in detail.

For example, in a NAND flash memory, as a method of injecting electrons into a charge storage layer, a method of injecting charges into the charge storage layer by an FN tunnel current is known. In this case, a high program voltage is applied to the control gate of the selected memory cell MC. The program voltage does not depend on the size of the memory cell MC. Therefore, the withstand voltage limit between the selected word line WL and the unselected word line WL limits an interval between the word lines WL in the Z direction. In addition, if the total number of the word lines WL coupled to one NAND string NS increases, the area (number) of the high-voltage transistors that supply the program voltage increases, and the chip size increases.

On the other hand, with the configuration according to the present embodiment, the semiconductor memory device 1 can select at least one of the unselected word lines WL as the switch word line WL in the program operation. The semiconductor memory device 1 can apply a voltage VSW lower than the program voltage VPGM applied to the selected word line WL and the voltage VPASS applied to the unselected word line WL to the switch word line WL. The semiconductor memory device 1 can form an electric field between the drain and the source of the switch memory cell MC to generate hot carriers (high-temperature electrons). The semiconductor memory device 1 can inject high-temperature electrons into the charge storage layer of the selected memory cell MC. With the execution of the program operation by the HCI assist, the program voltage VPGM can be reduced as compared with the FN tunnel current method. Therefore, the semiconductor memory device 1 can reduce power consumption.

Furthermore, with the configuration according to the present embodiment, since the semiconductor memory device 1 can reduce the program voltage, the interval between the word lines WL in the Z direction can be reduced. Furthermore, with the configuration according to the present embodiment, it is possible to suppress an increase in the area of the high-voltage transistor that supplies the program voltage. Therefore, an increase in the chip size can be suppressed.

### 1.5 Modification of First Embodiment

Next, two modifications of the first embodiment will be described. Hereinafter, differences from the first embodiment will be mainly described.

### 1.5.1 First Modification of First Embodiment

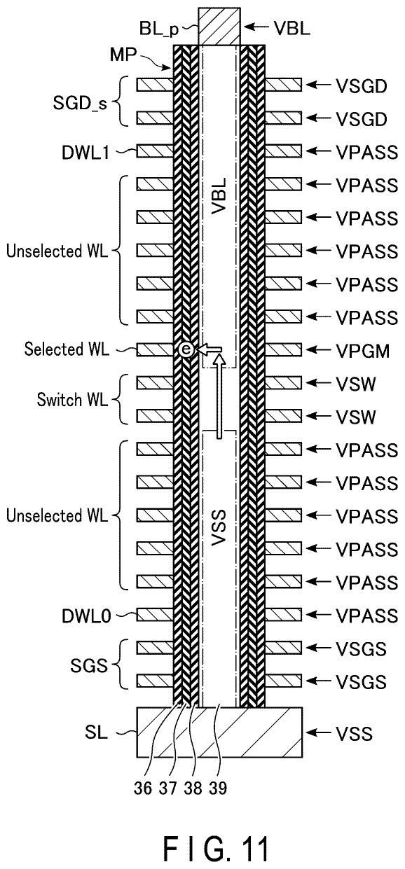

First, a first modification of the first embodiment will be described with reference to FIG. 11. In the first modification, a case where two switch word lines WL are selected will be described. FIG. 11 is a diagram illustrating an example of a relationship between a state of a channel of a memory pillar MP including a selected memory cell MC as a program target and a voltage of each interconnect during the program operation.

As shown in FIG. 11, two adjacent unselected word lines WL may be selected as the switch word lines WL. The number of the switch word lines WL may be three or more.

Two memory cells MC corresponding to each of the two switch word lines WL function as one switch memory cell MC. The effective channel length of the switch memory cell MC in a case where the number of the switch word lines WL is two is longer than the channel length of the switch memory cell MC in a case where the number of the switch word lines WL is one. Therefore, the voltage VSW in a case where the number of the switch word lines WL is two is set higher than the voltage VSW in a case where the number of the switch word lines WL is one.

### 1.5.2 Second Modification of First Embodiment

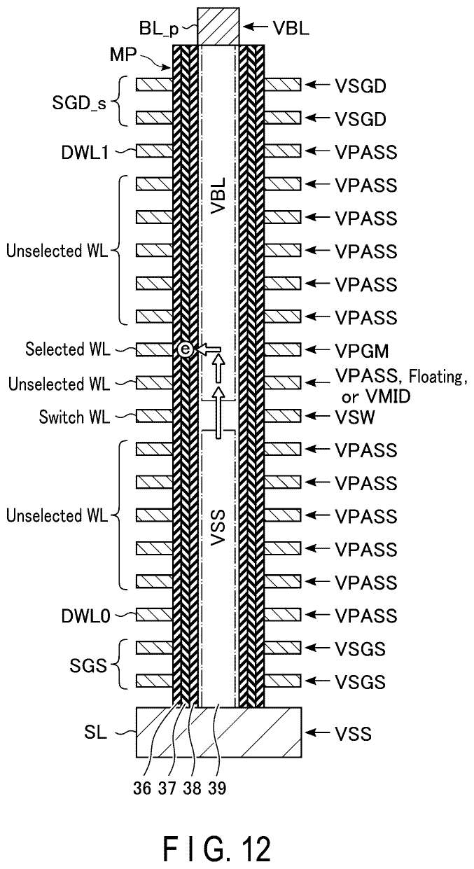

Next, a second modification of the first embodiment will be described with reference to FIG. 12. In the second modification, a case where the unselected word line WL is provided between the selected word line WL and the switch word line WL will be described. FIG. 12 is a diagram illustrating an example of a relationship between the state of the channel of the memory pillar MP including the selected memory cell MC as a program target and the voltage of each interconnect during the program operation.

As illustrated in FIG. 12, there may be an unselected word line WL between the selected word line WL and the switch word line WL. A voltage VMID may be applied to the unselected word line WL located between the selected word line WL and the switch word line WL, or may be in a floating state. The voltage VMID is higher than the voltage VBL and lower than the voltage VPASS.

The selection transistor ST1, the dummy memory cell DMC1, the unselected memory cells MC located on the bit line BL side from the switch memory cell MC, and the selected memory cell MC are in an on state. Therefore, a channel is formed in the semiconductor layer 39 from the end of the bit line BL side to the unselected word line WL located between the selected word line WL and the switch word line WL. The potential of the channel on the bit line BL side rises to the same voltage VBL as the bit line BL_p. In addition, the selection transistors ST2, the dummy memory cell DMC0, and the unselected memory cells MC located on the source line SL side from the switch memory cell MC are turned on. Therefore, a channel is formed in the semiconductor layer 39 from the end on the source line SL side to the unselected word line WL (unselected memory cell MC) that is adjacent to the switch word line WL in the source line SL side. The potential of the channel on the source line SL side is the same voltage VSS as the source line SL. Therefore, as in the first embodiment, an electric field is formed between the drain and the source of the switch memory cell MC. As a result, hot carriers are generated.

### 1.5.3 Effects According to Present Modification

With the configuration according to the first modification or the second modification, the same effects as those of the first embodiment can be obtained.

### 2. Second Embodiment

Next, a second embodiment will be described. In the second embodiment, a case where hot carriers are generated using channel boost will be described. Hereinafter, differences from the first embodiment will be mainly described.

### 2.1 Program Operation

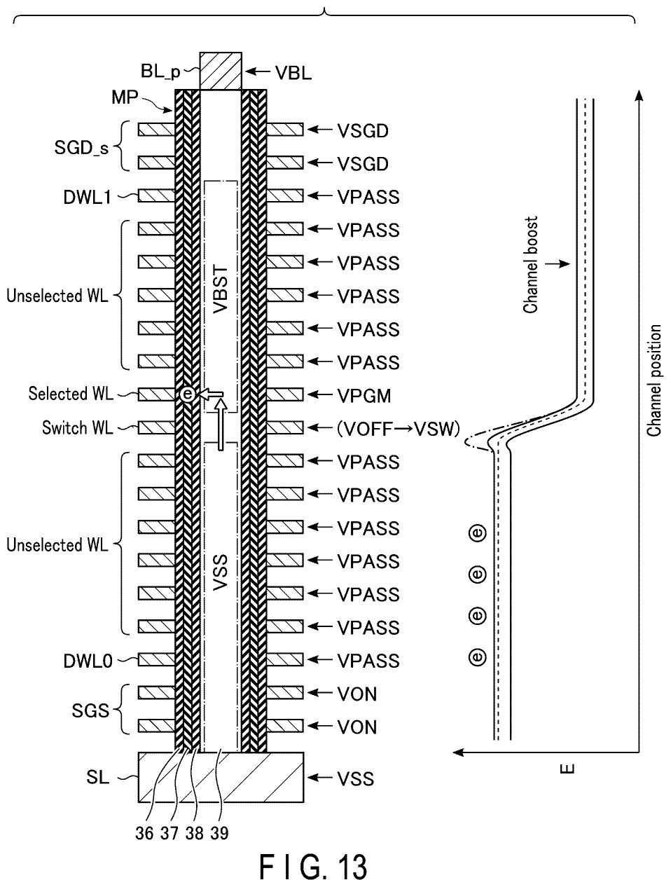

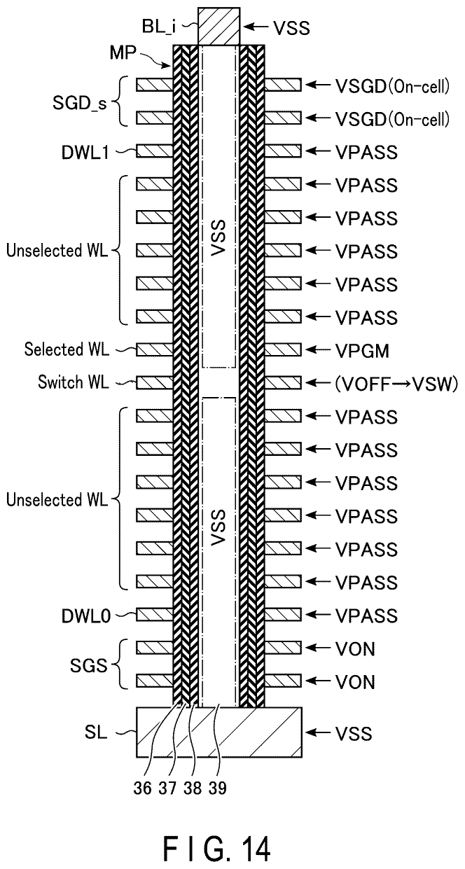

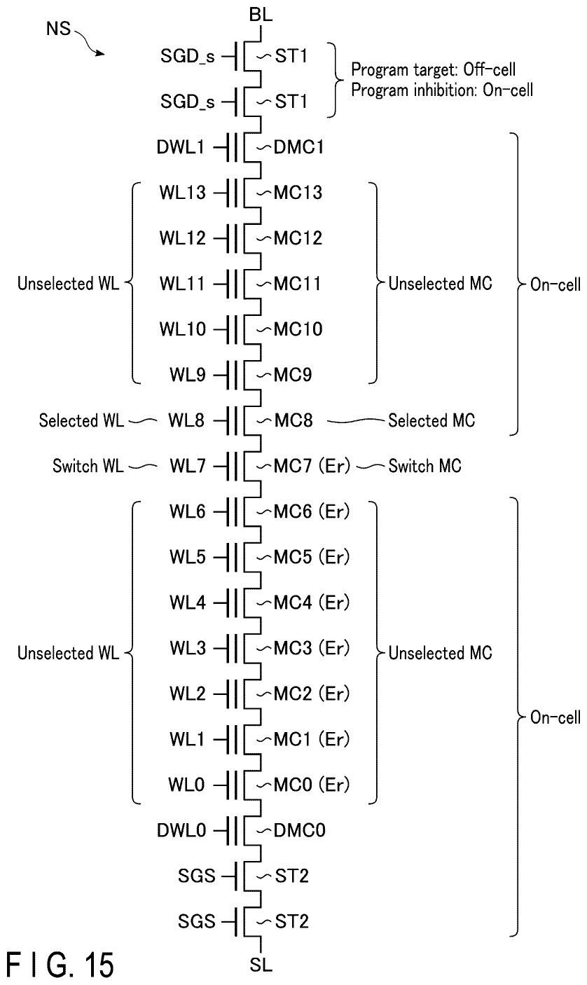

First, an example of a program operation in the present embodiment will be described with reference to FIGS. 13 to 15. FIG. 13 is a diagram illustrating an example of a relationship among a state of a channel of a memory pillar MP including a selected memory cell MC as a program target, a voltage of each interconnect, and a band diagram of the channel during a program operation. FIG. 14 is a diagram illustrating an example of a relationship between the state of the channel of the memory pillar MP including a program-inhibited selected memory cell MC and the voltage of each interconnect during the program operation. FIG. 15 is a diagram illustrating an example of a state of each transistor in a NAND string NS during the program operation.

As illustrated in FIGS. 13 and 14, voltages applied to bit lines BL_p and BL_i, a source line SL, select gate lines SGS, a selected word line WL, unselected word lines WL, and dummy word lines WL are similar to those described in the first embodiment with reference to FIGS. 6 and 7.

In the present embodiment, a row decoder 18 applies a voltage VSGD to the select gate lines SGD_s. The voltage VSGD is higher than the voltage VSS and lower than the voltage VBL. As illustrated in FIG. 15, in the memory pillar MP (NAND string NS) corresponding to a program target, since the voltage VBL is applied to the bit line BL_p, the selection transistors ST1 are in a cutoff state. Hereinafter, the transistor in the cutoff state is also referred to as “off-cell”. On the other hand, in the memory pillar MP (NAND string NS) corresponding to program inhibition, since the voltage VSS is applied to the bit line BL_i, the selection transistors ST1 are turned on.

As illustrated in FIG. 13, the row decoder 18 first applies a voltage VOFF to a switch word line WL. The voltage VOFF is lower than the voltage VSW. The voltage VOFF is a voltage for turning off the memory cell MC. As a result, in the memory pillar MP corresponding to the program target, a semiconductor layer 39 from the select gate line SGD_s to the switch word line WL is in the floating state. In this state, the row decoder 18 applies the voltage VPGM to the selected word line WL and applies the voltage VPASS to the unselected word lines WL. Then, the potential of the semiconductor layer 39 increases due to coupling between the selected word line WL and the unselected word lines WL, and the semiconductor layer 39 (hereinafter, referred to as “channel boost”). As a result, a channel on the bit line BL side is formed between the select gate line SGD_s and the switch word line WL. A boost voltage of the channel at this time is VBST. The voltage VBST is a voltage higher than the voltage VSS.

The potential of the channel on the source line SL side is the same voltage VSS as that of the source line SL as in the first embodiment. Therefore, an electric field is formed between the drain and the source of the switch memory cell MC due to a potential difference between the voltage VBST and the voltage VSS.

Therefore, as in the band diagram of the channel illustrated in FIG. 13, the band (potential) is bent in the region corresponding to the switch word line WL (switch memory cell MC).

In this state, the row decoder 18 applies the voltage VSW to the switch word line WL. As a result, electrons on the source line SL side are injected into the bit line BL side beyond a potential barrier. That is, hot carriers are generated. The electrons injected into the channel on the bit line BL side are injected into the charge storage layer 37 of the selected memory cell MC as the program target by a potential difference between the selected word line WL and the channel. In a case where the voltage VSW is not applied to the switch word line WL and the switch memory cell MC is in the cutoff state, the potential barrier from the source line SL side to the bit line BL side indicated by a one-dot chain line is larger than that indicated by a solid line.

As illustrated in FIG. 14, in a case where the above-described voltages are applied to the memory pillar MP including the program-inhibited selected memory cell MC, the selection transistors ST1 are turned on. Therefore, similarly to the description using FIG. 7 of the first embodiment, the potential of the channel on the bit line BL side is the same voltage VSS as the bit line BL_i. Therefore, no electric field is formed between the drain and the source of the switch memory cell MC. That is, hot carriers are not generated. Therefore, electrons are not injected into the charge storage layer 37 of the program-inhibited selected memory cell MC.

### 2.2 Voltage of Each Interconnect During Program Operation

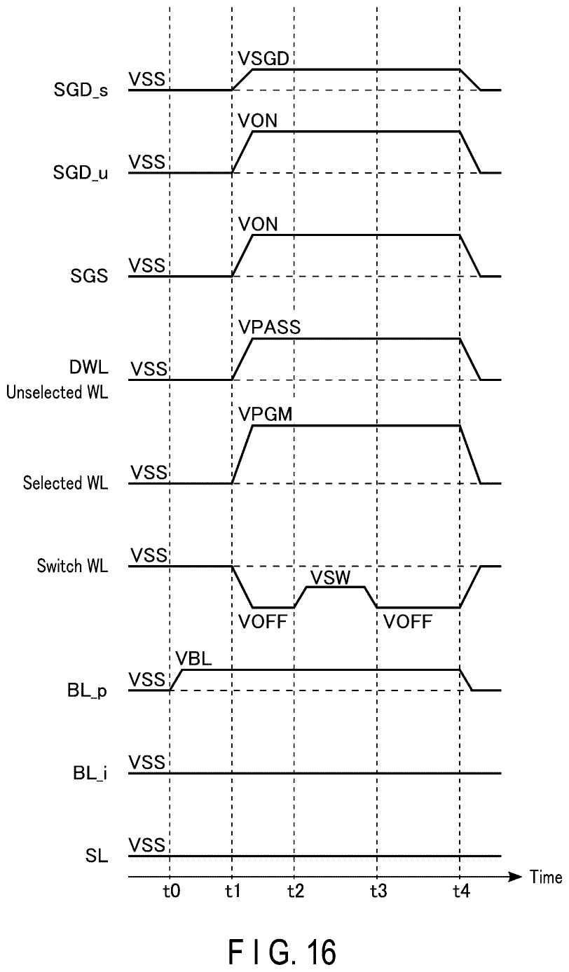

Next, an example of the voltage of each interconnect during the program operation will be described with reference to FIG. 16. FIG. 16 is a timing chart illustrating an example of the voltage of each interconnect during the program operation.

As illustrated in FIG. 16, first, at time t0, the sense amplifier 19 applies the voltage VBL to the bit line BL_p. In addition, the sense amplifier 19 applies the voltage VSS to the bit line BL_i. The row decoder 18 applies the voltage VSS to select gate lines SGD_s and SGD_u, the select gate lines SGS, the dummy word lines DWL, the unselected word lines WL, the selected word line WL, and the switch word line WL. The voltage VSS is applied to the source line SL.

Next, at time t1, the row decoder 18 applies the voltage VSGD to the select gate lines SGD_s. As a result, the selection transistors ST1 corresponding to the program target of the selected string unit SU are turned off. The selection transistors ST1 corresponding to the program inhibition of the selected string unit SU are turned on. The row decoder 18 applies the voltage VON to the select gate lines SGD_u and the select gate lines SGS. As a result, the selection transistors ST2 and the selection transistors ST1 of the unselected string unit SU are turned on. Further, the row decoder 18 applies the voltage VOFF to the switch word line WL. As a result, the switch memory cell MC is turned off. As a result, in the memory pillar MP corresponding to the program target of the selected string unit SU, the semiconductor layer 39 from the select gate line SGD_s to the switch word line WL is in the floating state.

In this state, the row decoder 18 applies the voltage VPASS to the dummy word lines DWL and the unselected word lines WL. In addition, the row decoder 18 applies the voltage VPGM to the selected word line WL. As a result, the dummy memory cells DMC, the unselected memory cells MC, and the selected memory cell MC are turned on. In the memory pillar MP corresponding to the program target of the selected string unit SU, the channel boosted to the voltage VBST is formed between the select gate line SGD_s and the switch word line WL by channel boost.

Next, at time t2, the row decoder 18 applies the voltage VSW to the switch word line WL. As a result, hot carriers (electrons) are generated in the switch memory cell MC corresponding to the program target. The generated electrons are injected into the charge storage layer 37 of the selected memory cell MC corresponding to the program target. During a period from time t2 to time t3, injection of electrons is executed.

Next, at time t3, the row decoder 18 applies the voltage VOFF to the switch word line WL.

Next, at time t4, the row decoder 18 applies the voltage VSS to the select gate lines SGD_s and SGD_u, the select gate lines SGS, the dummy word lines DWL, the unselected word lines WL, the selected word line WL, and the switch word line WL. In addition, the sense amplifier 19 applies the voltage VSS to the bit line BL_p. As a result, the program operation ends.

### 2.3 Effects According to Present Embodiment

With the configuration according to the present embodiment, the same effects as those of the first embodiment can be obtained.

Note that the first modification or the second modification of the first embodiment can be applied to the present embodiment. That is, a plurality of adjacent switch word lines WL may be selected, or an unselected word line WL may be provided between the selected word line WL and the switch word line WL.

### 3. Modifications and the Like

A semiconductor memory device according to the above embodiments includes: a first memory string (NS) including a first selection transistor (ST1), a first memory cell (selected MC), a second memory cell (switch MC), a third memory cell (unselected MC), and a second selection transistor (ST2) in which current paths are coupled in series; a bit line (BL) coupled to the first selection transistor; a source line (SL) coupled to the second selection transistor; a first select gate line (SGD_s) coupled to a gate of the first selection transistor; a second select gate line (SGS) coupled to a gate of the second selection transistor; a first word line (selected WL) coupled to a gate of the first memory cell; a second word line (switch WL) coupled to a gate of the second memory cell; a third word line (unselected WL) coupled to a gate of the third memory cell; and a control circuit (14) configured to execute a write operation including a program operation and a program verify operation. In a case where data is written to the first memory cell in the program operation of the first memory cell, the control circuit is configured to: apply a first voltage (VBL) to the bit line BL; apply a second voltage (VSS) lower than the first voltage to the source line; apply a third voltage (VON) higher than the first voltage to the first select gate line; apply a fourth voltage (VON) higher than the first voltage to the second select gate line; apply a program voltage (VPGM) to the first word line; apply a fifth voltage (VSW) to the second word line; and apply a sixth voltage (VPASS) higher than the fifth voltage and lower than the program voltage to the third word line.

The semiconductor memory device can reduce power consumption as long as it has the configuration according to the above embodiment.

Note that the present invention is not limited to the above-described embodiment, and various modifications can be applied.

For example, in the above embodiment, the case where the memory cell MC is sequentially selected from the memory cell MC on the bit line BL side in the data write order in the NAND string NS has been described, but the memory cell MC may be sequentially selected from the memory cell MC on the source line SL side. In this case, the switch word line WL is selected from the unselected word lines WL located on the bit line BL side from the selected word line WL. Similarly to the above embodiment, the order in which the voltages are applied to the selected word line WL, the switch word line WL, and the bit line BL_p can be arbitrarily set.

Furthermore, the “couple” in the above embodiments includes a state where coupling is indirectly made by interposing, for example, other components such as a transistor or a resistor between components to be coupled.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a first memory string including a first selection transistor, a first memory cell, a second memory cell, a third memory cell, and a second selection transistor in which current paths are coupled in series;
a bit line coupled to the first selection transistor;
a source line coupled to the second selection transistor;
a first select gate line coupled to a gate of the first selection transistor;
a second select gate line coupled to a gate of the second selection transistor;
a first word line coupled to a gate of the first memory cell;
a second word line coupled to a gate of the second memory cell;
a third word line coupled to a gate of the third memory cell; and
a control circuit configured to execute a write operation including a program operation and a program verify operation, wherein
in a case where data is written to the first memory cell in the program operation of the first memory cell, the control circuit is configured to:
apply a first voltage to the bit line BL;
apply a second voltage lower than the first voltage to the source line;
apply a third voltage higher than the first voltage to the first select gate line;
apply a fourth voltage higher than the first voltage to the second select gate line;
apply a program voltage to the first word line;
apply a fifth voltage to the second word line; and
apply a sixth voltage higher than the fifth voltage and lower than the program voltage to the third word line.

2. The semiconductor memory device according to claim 1, wherein
the control circuit is further configured to;
execute the write operation of the second memory cell after the write operation of the first memory cell; and
execute the write operation of the third memory cell after the write operation of the second memory cell.

3. The semiconductor memory device according to claim 1, wherein
the control circuit is further configured to apply the second voltage to the bit line BL in a case where data is not written to the first memory cell in the program operation of the first memory cell.

4. The semiconductor memory device according to claim 1, wherein
the first selection transistor in which the third voltage is applied to the first select gate line, the second selection transistor in which the fourth voltage is applied to the second select gate line, the first memory cell in which the program voltage is applied to the first word line, and the third memory cell in which the sixth voltage is applied to the third word line are turned on.

5. The semiconductor memory device according to claim 1, further comprising:
a second memory string including a third selection transistor, a fourth memory cell, a fifth memory cell, a sixth memory cell, and a fourth selection transistor in which current paths are coupled in series; and
a third select gate line coupled to a gate of the third selection transistor, wherein
the third selection transistor is coupled to the bit line,
the fourth selection transistor is coupled to the source line,
a gate of the fourth selection transistor is coupled to the second select gate line,
a gate of the fourth memory cell is coupled to the first word line,
a gate of the fifth memory cell is coupled to the second word line,
a gate of the sixth memory cell is coupled to the third word line, and
the control circuit is further configured to apply the second voltage to the third select gate line in the program operation of the first memory cell.

6. The semiconductor memory device according to claim 5, wherein
the third selection transistor in which the second voltage is applied to the third select gate line is turned off.

7. The semiconductor memory device according to claim 1, wherein
the first voltage is higher than the second voltage by 1 V or more.

8. The semiconductor memory device according to claim 1, wherein
the fifth voltage is equal to or lower than a threshold voltage of the second memory cell.

9. The semiconductor memory device according to claim 1, wherein
in the program operation of the first memory cell, the first voltage is applied to the drain of the second memory cell, the second voltage is applied to a source of the second memory cell, and hot carriers are generated based on a voltage difference between the first voltage and the second voltage.

10. The semiconductor memory device according to claim 1, further comprising a fifth word line, wherein
the first memory string further includes an eighth memory cell provided between the first memory cell and the second memory cell and having a gate coupled with the fifth word line, and
the control circuit is further configured to apply the fifth voltage to the fifth word line in the program operation of the first memory cell.

11. The semiconductor memory device according to claim 1, further comprising a sixth word line, wherein
the first memory string further includes a ninth memory cell provided between the first memory cell and the second memory cell and having a gate coupled with the sixth word line, and
the control circuit is further configured to apply a seventh voltage higher than the first voltage and lower than the sixth voltage to the sixth word line in the program operation of the first memory cell.

12. A semiconductor memory device, comprising:
a first memory string including a first selection transistor, a first memory cell, a second memory cell, a third memory cell, and a second selection transistor in which current paths are coupled in series;
a bit line coupled to the first selection transistor;
a source line coupled to the second selection transistor;
a first select gate line coupled to a gate of the first selection transistor;
a second select gate line coupled to a gate of the second selection transistor;
a first word line coupled to a gate of the first memory cell;
a second word line coupled to a gate of the second memory cell;
a third word line coupled to a gate of the third memory cell; and
a control circuit configured to execute a write operation including a program operation and a program verify operation, wherein
in a case where data is written to the first memory cell in the program operation of the first memory cell, the control circuit is configured to:
apply a first voltage to the bit line BL;
apply a second voltage lower than the first voltage to the source line;
apply a third voltage higher than the second voltage and lower than the first voltage to the first select gate line;
apply a fourth voltage higher than the first voltage to the second select gate line;
apply a program voltage to the first word line;
apply a fifth voltage to the second word line; and
apply a sixth voltage higher than the fifth voltage and lower than the program voltage to the third word line.

13. The semiconductor memory device according to claim 12, wherein
the first selection transistor in which the third voltage is applied to the first select gate line and the second memory cell in which the fifth voltage is applied to the second word line are turned off, and
the second selection transistor in which the fourth voltage is applied to the second select gate line, the first memory cell in which the program voltage is applied to the first word line, and the third memory cell in which the sixth voltage is applied to the third word line are turned on.

14. The semiconductor memory device according to claim 12, wherein
the control circuit is further configured to apply the second voltage to the bit line BL in a case where data is not written to the first memory cell in the program operation of the first memory cell.

15. The semiconductor memory device according to claim 14, wherein
the first selection transistor in which the first voltage is applied to the current path and in which the third voltage is applied to the first select gate line is turned off.

16. The semiconductor memory device according to claim 12, wherein
the control circuit is further configured to apply a seventh voltage higher than the fifth voltage and lower than the sixth voltage after applying the fifth voltage to the second word line in the program operation of the first memory cell.

17. The semiconductor memory device according to claim 12, further comprising:
a second memory string including a third selection transistor, a fourth memory cell, a fifth memory cell, a sixth memory cell, and a fourth selection transistor in which current paths are coupled in series; and
a third select gate line coupled to a gate of the third selection transistor, wherein
the third selection transistor is coupled to the bit line,
the fourth selection transistor is coupled to the source line,
a gate of the fourth selection transistor is coupled to the second select gate line,
a gate of the fourth memory cell is coupled to the first word line,
a gate of the fifth memory cell is coupled to the second word line,
a gate of the sixth memory cell is coupled to the third word line, and
the control circuit is further configured to apply an eighth voltage higher than the first voltage to the third select gate line in the program operation of the first memory cell.
